(19) United States
(12) Patent Application Publication
(10) Pub. No.: US 2023/0290654 A1
(43) Pub. Date: Sep. 14, 2023

(54) LIGHT-EMISSION HEAT TREATMENT APPARATUS

(71) Applicant: SCREEN Holdings Co., Ltd., Kyoto (JP)

(72) Inventors: Ryuta TOBE, Kyoto-shi (JP); Naoto MORI, Kyoto-shi (JP); Takahiro KITAZAWA, Kyoto-shi (JP)

(21) Appl. No.: 18/074,785

(22) Filed: Dec. 5, 2022

(30) Foreign Application Priority Data
Mar. 9, 2022 (JP) 2022-035951

(51) Int. Cl. H01L 21/67; H05B 1/02; H05B 3/00

(52) U.S. Cl. CPC H01L 21/67115; H05B 1/0233; H05B 3/0047; F27B 17/0025

(57) ABSTRACT

A flash lamp emits a flash of light to a front surface of a semiconductor wafer held in a chamber to heat the semiconductor wafer. A GCT thyristor is connected in parallel with the flash lamp. After a lapse of a predetermined time period since a current starts to flow through the flash lamp, the GCT thyristor enters an ON state. This allows a discharge current to flow through the GCT thyristor with a smaller impedance, and prevents any current from flowing through the flash lamp. Consequently, a tail current flowing through the flash lamp can be suppressed. Furthermore, reduction in a voltage charged into a capacitor can prevent the life of the flash lamp from being shortened.

### BACKGROUND OF THE INVENTION

### Field of the Invention

The present invention relates to a heat treatment apparatus that heats a substrate by emitting a flash of light to the substrate. Examples of the substrate to be treated include a semiconductor wafer, a substrate for liquid crystal display, a substrate for flat panel display (FPD), a substrate for optical disk, a substrate for magnetic disk, and a substrate for solar cell.

### Description of the Background Art

In processes of manufacturing semiconductor devices, attention is being given to flash lamp annealing (FLA) for heating semiconductor wafers in a very short time period. The flash lamp annealing relates to a heat treatment technology for increasing the temperature of only the front surface of a semiconductor wafer in a very short time period (shorter than or equal to several milliseconds) by emitting a flash of light to the front surface using a xenon flash lamp (simply being referred to as “a flash lamp” will mean this xenon flash lamp hereinafter).

The spectral power distribution of xenon flash lamps ranges from the ultraviolet region to the near-infrared region. The light produced by the xenon flash lamps has wavelengths shorter than those of conventional halogen lamps, and almost coincides in fundamental absorption band with semiconductor wafers made of silicon. Thus, when the xenon flash lamp emits a flash of light to the semiconductor wafer, it can rapidly increase the temperature of the semiconductor wafer with less transmitted light. It turns out that temperatures of only the vicinity of the front surface of the semiconductor wafer can be selectively increased with emission of a flash of light in a very short time period less than or equal to several milliseconds.

This kind of flash lamp annealing is applied to treatment requiring heating for a very short time period, for example, typically to activation of impurities implanted into semiconductor wafers. When each flash lamp emits a flash of light to the front surface of the semiconductor wafer into which impurities have been implanted by an ion implantation method, the temperature of the front surface of the semiconductor wafer can be increased to an activation temperature for only a very short time period, which allows only activation of the impurities without deeply diffusing the impurities.

US2009/0067823 and Japanese Patent Application Laid-Open No. 2011-119562 (hereinafter referred to as Patent Documents 1 and 2) each disclose a heat treatment apparatus which includes such xenon flash lamps. Each of the xenon flash lamps includes a light emission circuit in which an insulated gate bipolar transistor (IGBT) is connected for controlling emission of the flash lamp. Each of the disclosed apparatuses can control emission of the lamp light by feeding a predetermined pulse signal to a gate of the IGBT to define a waveform of a current flowing through the flash lamp. Thus, the apparatuses can freely adjust the emission time and the emission intensity of the flash lamps.

Processes of manufacturing recent leading-edge semiconductors require a technology for annealing with a low heat history to accommodate a change in material or structure, while the semiconductors are heated to high temperatures. The “annealing with a low heat history” means heat treatment requiring less total heat charged into a semiconductor wafer. Flash lamp annealing requires rapidly heating the front surface of the semiconductor wafer to high temperatures for a shorter time period. This requires emitting a high-intensity flash of light to the semiconductor wafer for a shorter period of emission time.

This emission of the flash of light that accommodates the low heat history requires instantaneously feeding a large current to the flash lamp. For example, heating the front surface of the semiconductor wafer to 600° C. or more with emission of a flash of light for an emission time of 0.1 millisecond requires instantaneously feeding a current larger than or equal to 4000 A to the flash lamp. To accommodate such a large current, the rated current of circuit elements included in the light emission circuit of the flash lamp needs to exceed 4000 A.

However, the IGBTs incorporated into the light emission circuits of the flash lamps disclosed in Patent Documents 1 and 2 include no element that can withstand the current as large as 4000 A. Thus, the IGBTs cannot be incorporated into the light emission circuit that can accommodate the emission time of 0.1 millisecond for the low heat history. When the IGBTs cannot be incorporated into the light emission circuit, the waveform of the current flowing through the flash lamp is a fixed waveform defined by, for example, a capacitor and a coil. In other words, the emission time of the flash lamp is determined by a capacitance of the capacitor and an inductance of the coil.

However, defining the waveform of the current flowing through the flash lamp by the capacitor and the coil creates a tail current. Thus, even after a lapse of 0.1 millisecond that is a planned emission time, the current continues to flow through the flash lamp. This continues the emission of light. Accordingly, the semiconductor wafer continues to be heated after the lapse of 0.1 millisecond. This reduces a cooling rate of the semiconductor wafer, and impairs lowering the heat history.

Furthermore, feeding, to the flash lamp, a current as large as 4000 A whose waveform is defined by the capacitor and the coil requires increasing the capacitance of the capacitor or the voltage charged into the capacitor. The increase in the capacitance of the capacitor prolongs the emission time of the flash lamp. Thus, the emission time as extremely short as 0.1 millisecond requires reducing the capacitance of the capacitor. This requires charging the capacitor with a very high voltage, which increases the discharge voltage to be applied to the flash lamp. As the voltage charged into the capacitor increases, problems occur, namely, the flash lamp is more easily damaged, and the life of the lamp is shortened.

### SUMMARY

This invention is directed to a heat treatment apparatus that heats a substrate by emitting a flash of light to the substrate.

According to an aspect of this invention, the heat treatment apparatus includes: a chamber housing the substrate; a holder holding the substrate in the chamber; a flash lamp emitting the flash of light to the substrate, the substrate being held by the holder; a discharge circuit allowing a current to flow through the flash lamp and causing the flash lamp to emit the flash of light; and a controller controlling the discharge circuit, wherein the discharge circuit includes a first switching element connected in parallel with the flash lamp, and the controller is configured to render the first switching element conductive to stop the emission of the flash lamp.

This can suppress the tail current flowing through the flash lamp, and prevent the life of the flash lamp from being shortened by reducing the voltage to be applied to the flash lamp.

Preferably, the first switching element is a gate commutated turn-off thyristor. The gate commutated turn-off thyristor can make the discharge current flowing through the flash lamp into a large current.

According to another aspect of this invention, the heat treatment apparatus includes: a chamber housing the substrate; a holder holding the substrate in the chamber; a flash lamp emitting the flash of light to the substrate, the substrate being held by the holder; a discharge circuit allowing a current to flow through the flash lamp and causing the flash lamp to emit the flash of light; and a controller controlling the discharge circuit, wherein the discharge circuit includes a gate commutated turn-off thyristor connected in series with the flash lamp, and the controller is configured to set the gate commutated turn-off thyristor in a blocking state to stop the emission of the flash lamp.

This can suppress the tail current flowing through the flash lamp, and prevent the life of the flash lamp from being shortened by reducing the voltage to be applied to the flash lamp.

Thereby, the object of this invention is to suppress the tail current and prevent the life of the flash lamp from being shortened.

### BRIEF DESCRIPTION OF THE DRAWINGS

FIG. 1 is a longitudinal sectional view showing a structure of a heat treatment apparatus according to the present invention;

FIG. 2 is a perspective view showing the entire external appearance of a holder;

FIG. 3 is a plan view of a susceptor;

FIG. 4 is a sectional view of the susceptor;

FIG. 5 is a plan view of a transfer mechanism;

FIG. 6 is a side view of the transfer mechanism;

FIG. 7 is a plan view showing an arrangement of multiple halogen lamps;

FIG. 8 illustrates a discharge circuit of a flash lamp according to Embodiment 1;

FIG. 9 is a block diagram illustrating a configuration of a controller;

FIG. 10 illustrates a current flowing through the flash lamps according to Embodiment 1;

FIG. 11 illustrates a discharge circuit of a flash lamp according to Embodiment 2;

FIG. 12 illustrates a current flowing through the flash lamps according to Embodiment 2; and

FIG. 13 illustrates a discharge circuit of a flash lamp according to Embodiment 3.

### DESCRIPTION OF THE PREFERRED EMBODIMENTS

Preferred embodiments of the present invention will be described in detail with reference to the drawings. Unless otherwise noted, the expressions indicating relative or absolute positional relationships (e.g., “in one direction”, “along one direction”, “parallel”, “orthogonal”, “central”, “concentric”, and “coaxial”) include those exactly indicating the positional relationships and those where an angle or a distance is relatively changed within tolerance or to the extent that similar functions can be obtained. Unless otherwise noted, the expressions indicating equality (e.g., “same”, “equal”, “uniform”, and “homogeneous”) include those indicating quantitatively exact equality and those in the presence of a difference within tolerance or to the extent that similar functions can be obtained. Unless otherwise noted, the expressions indicating shapes (e.g., “circular”, “rectangular” or “cylindrical”) include those indicating geometrically exact shapes and those indicating, for example, roughness or a chamfer to the extent that similar advantages can be obtained. An expression “comprising”, “including”, “containing”, or “having” a certain constituent element is not an exclusive expression for excluding the presence of the other constituent elements. An expression “at least one of A, B, and C” involves “only A”, “only B”, “only C”, “arbitrary two of A, B, and C”, and “all of A, B, and C”.

### Embodiment 1

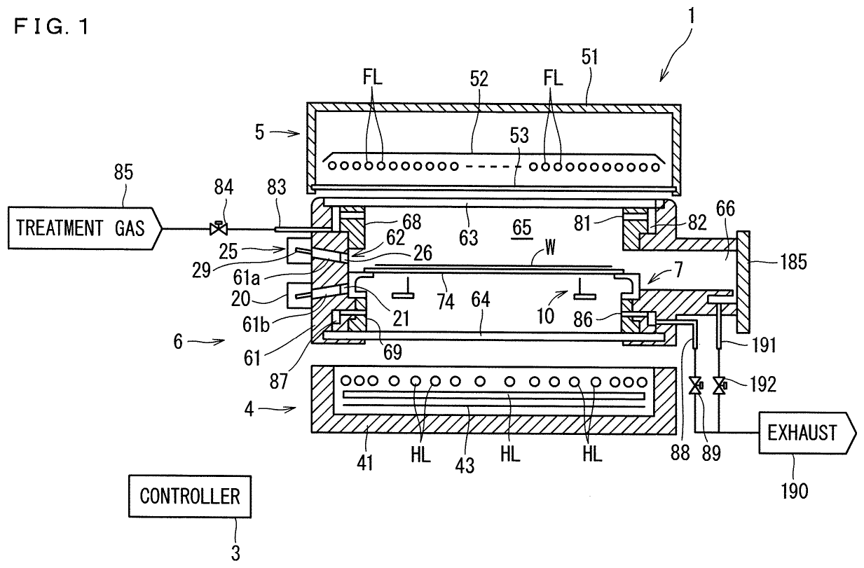

FIG. 1 is a longitudinal sectional view showing a structure of a heat treatment apparatus 1 according to the present invention. The heat treatment apparatus 1 in FIG. 1 is a flash lamp annealer that heats a disk-shaped semiconductor wafer W serving as a substrate by emitting a flash of light to the semiconductor wafer W. The size of the semiconductor wafer W to be treated is, but not particularly limited to, for example, 300 mm or 450 mm in diameter (300 mm in diameter in Embodiment 1). Impurities are implanted into the semiconductor wafer W before being transported into the heat treatment apparatus 1. The heat treatment of the heat treatment apparatus 1 initiates a process of activating the implanted impurities. It should be noted that dimensions and the number of components in FIG. 1 and the subsequent figures are shown in exaggeration or in simplified form as appropriate for the sake of easier understanding.

The heat treatment apparatus 1 includes a chamber 6 that houses the semiconductor wafer W, a flash heater 5 including a plurality of flash lamps FL, and a halogen heater 4 including a plurality of halogen lamps HL. The flash heater 5 is provided above the chamber 6, and the halogen heater 4 is provided below the chamber 6. The heat treatment apparatus 1 also includes, within the chamber 6, a holder 7 that holds the semiconductor wafer W in a horizontal attitude, and a transfer mechanism 10 that transfers the semiconductor wafer W between the holder 7 and the outside of the apparatus. The heat treatment apparatus 1 further includes a controller 3 that controls operating mechanisms located in the halogen heater 4, the flash heater 5, and the chamber 6 for heat treatment of the semiconductor wafer W.

The chamber 6 includes quartz chamber windows attached to the top and bottom of a chamber side portion 61 that is tubular. The chamber side portion 61 is substantially tubular with the top and bottom opened. The top opening has a top chamber window 63 that is closed, and the bottom opening has a bottom chamber window 64 that is closed. The top chamber window 63, which forms the ceiling portion of the chamber 6, is a disk-shaped member made of quartz and functions as a quartz window that allows the flash of light emitted from the flash heater 5 to pass through the chamber 6. The bottom chamber window 64, which forms the floor of the chamber 6, is also a disk-shaped member made of quartz and functions as a quartz window that allows light emitted from the halogen heater 4 to pass through the chamber 6.

A reflection ring 68 is mounted on the upper portion of the inner wall surface of the chamber side portion 61, and a reflection ring 69 is mounted on the lower portion thereof. Both of the reflection rings 68 and 69 are formed annular. The upper reflection ring 68 is fitted from above the chamber side portion 61. On the other hand, the lower reflection ring 69 is fitted from below the chamber side portion 61 and fastened with screws that are not illustrated. In other words, the reflection rings 68 and 69 are both removably mounted on the chamber side portion 61. An interior space of the chamber 6, i.e. a space surrounded by the top chamber window 63, the bottom chamber window 64, the chamber side portion 61, and the reflection rings 68 and 69, is defined as a heat treatment space 65.

A recessed portion 62 is formed in the inner wall surface of the chamber 6 by fitting the reflection rings 68 and 69 to the chamber side portion 61. In other words, the recessed portion 62 is formed by being surrounded by a lower end face of the reflection ring 68, an upper end face of the reflection ring 69, and a central portion of the inner wall surface of the chamber side portion 61 to which the reflection rings 68 and 69 are not fitted. The recessed portion 62 is formed annular horizontally along the inner wall surface of the chamber 6, and surrounds the holder 7 that holds the semiconductor wafer W. The chamber side portion 61 and the reflection rings 68 and 69 are made of a metal material (e.g., stainless steel) superior in strength and heat resistance.

The chamber side portion 61 has a transport opening (throat) 66 through which the semiconductor wafer W is transported into and out of the chamber 6. The transport opening 66 is openable and closable with a gate valve 185. The transport opening 66 is connected in communication with an outer peripheral surface of the recessed portion 62. Thus, when the transport opening 66 is opened by the gate valve 185, the semiconductor wafer W can be transported into and out of the heat treatment space 65 through the transport opening 66 and the recessed portion 62. When the transport opening 66 is closed by the gate valve 185, the heat treatment space 65 in the chamber 6 is made airtight.

The chamber side portion 61 is further provided with a through hole 61a and a through hole 61b both bored therein. The through hole 61a is a cylindrical hole for directing infrared light radiated from an upper surface of the semiconductor wafer W held by a susceptor 74 to be described later, to an infrared sensor 29 of an upper radiation thermometer 25. The through hole 61b is a cylindrical hole for directing infrared light radiated from a lower surface of the semiconductor wafer W to a lower radiation thermometer 20. The through holes 61a and 61b are inclined with respect to a horizontal direction so that the longitudinal axes of the respective through holes 61a and 61b intersect a main surface of the semiconductor wafer W held by the susceptor 74. A transparent window 26 made of calcium fluoride transparent to infrared light in a wavelength range measurable with the upper radiation thermometer 25 is mounted to an end portion of the through hole 61a which faces the heat treatment space 65. A transparent window 21 made of barium fluoride transparent to infrared light in a wavelength range measurable with the lower radiation thermometer 20 is mounted to an end portion of the through hole 61b which faces the heat treatment space 65.

A gas supply opening 81 for supplying the heat treatment space 65 with a treatment gas is formed in an upper portion of the inner wall of the chamber 6. The gas supply opening 81 is formed above the recessed portion 62, and may be provided in the reflection ring 68. The gas supply opening 81 is connected in communication with a gas supply pipe 83 through a buffer space 82 formed annular inside the side wall of the chamber 6. The gas supply pipe 83 is connected to a treatment gas supply source 85. A valve 84 is inserted at some midpoint in the gas supply pipe 83. When the valve 84 is opened, the treatment gas is fed from the treatment gas supply source 85 to the buffer space 82. The treatment gas flowing in the buffer space 82 flows to be spread within the buffer space 82, which is lower in fluid resistance than that of the gas supply opening 81, and is supplied into the heat treatment space 65 through the gas supply opening 81. Examples of the treatment gas can include inert gases such as nitrogen gas (N₂), reactive gases such as hydrogen (H₂) and ammonia (NH₃), and mixtures of these gases (nitrogen gas in Embodiment 1).

A gas exhaust opening 86 for exhausting a gas from the heat treatment space 65 is formed in a lower portion of the inner wall of the chamber 6. The gas exhaust opening 86 is formed below the recessed portion 62, and may be provided in the reflection ring 69. The gas exhaust opening 86 is connected in communication with a gas exhaust pipe 88 through a buffer space 87 formed annular inside the side wall of the chamber 6. The gas supply pipe 88 is connected to an exhaust part 190. A valve 89 is inserted at some midpoint in the gas exhaust pipe 88. When the valve 89 is opened, the gas in the heat treatment space 65 is exhausted to the gas exhaust pipe 88 through the gas exhaust opening 86 and the buffer space 87. The gas supply opening 81 and the gas exhaust opening 86 may be formed in a plurality of portions in a circumferential direction of the chamber 6, and may be slits. The treatment gas supply source 85 and the exhaust part 190 may be mechanisms provided in the heat treatment apparatus 1, or utility systems in a factory in which the heat treatment apparatus 1 is installed.

A gas exhaust pipe 191 for exhausting the gas from the heat treatment space 65 is also connected to a distal end of the transport opening 66. The gas exhaust pipe 191 is connected to the exhaust part 190 through a valve 192. By opening the valve 192, the gas in the chamber 6 is exhausted through the transport opening 66.

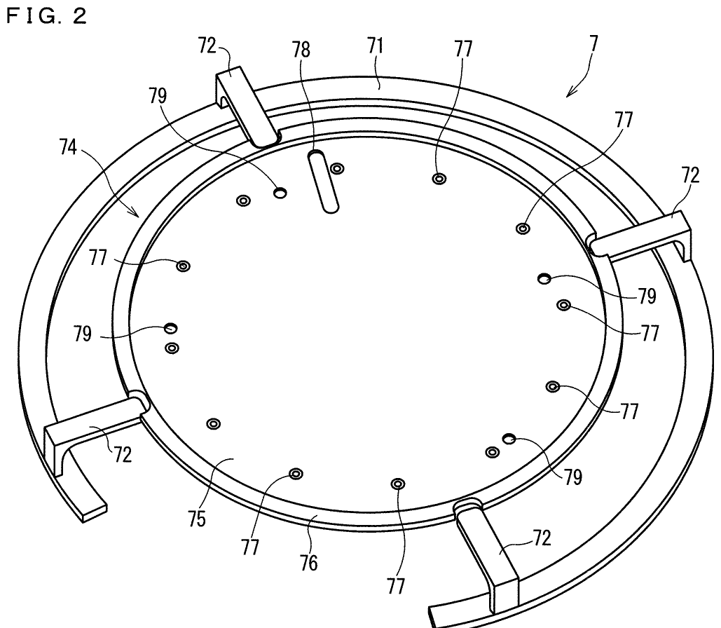

FIG. 2 is a perspective view showing the entire external appearance of the holder 7. The holder 7 holds the semiconductor wafer W in the chamber 6. The holder 7 includes a base ring 71, coupling portions 72, and a susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (see FIG. 1). The multiple coupling portions 72 (four coupling portions 72 in Embodiment 1) are mounted upright on the upper surface of the base ring 71 and arranged in a circumferential direction of the annular shape thereof. The coupling portions 72 are quartz members, and are rigidly secured to the base ring 71 by welding.

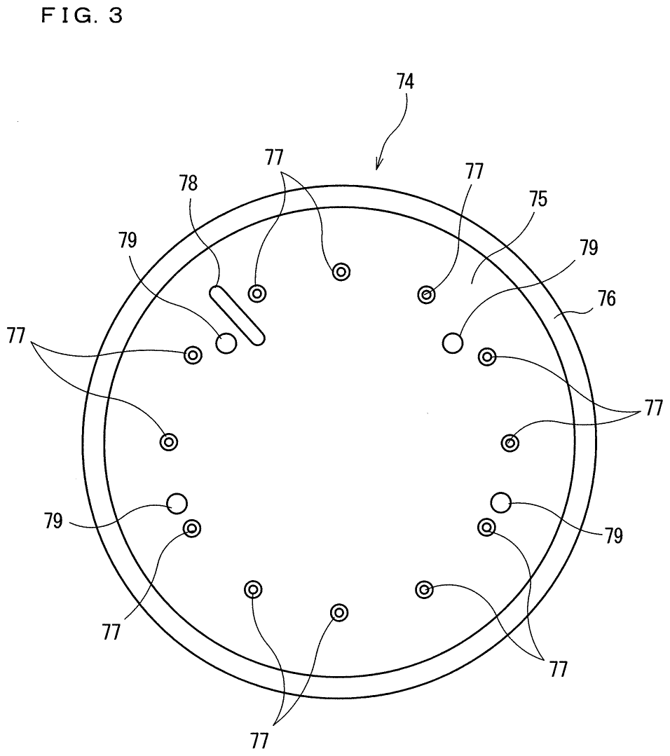

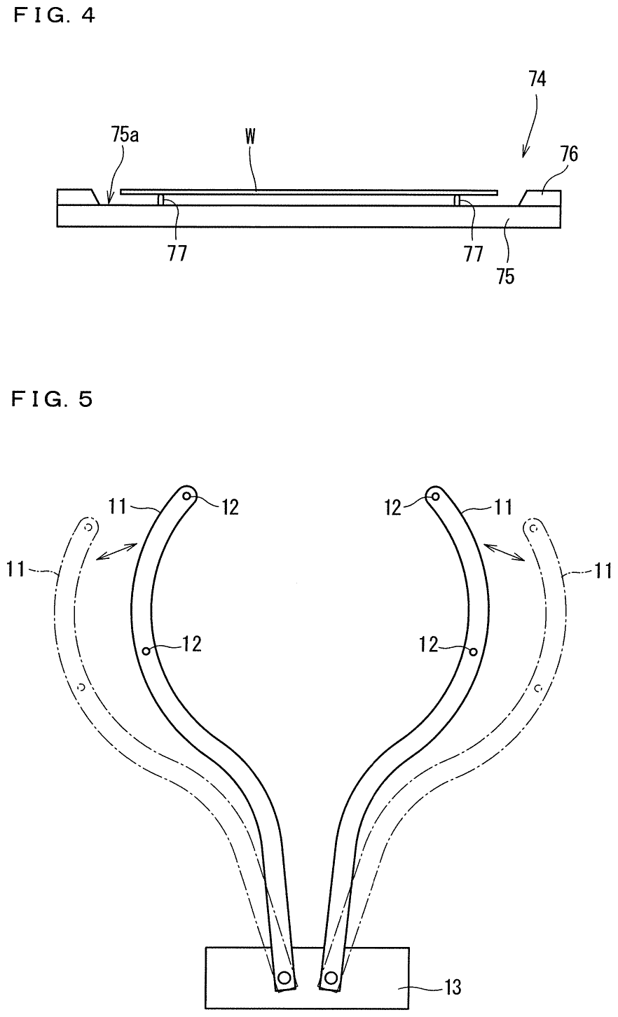

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a roughly circular and planar member made of quartz. The diameter of the holding plate 75 is greater than that of the semiconductor wafer W. In other words, the holding plate 75 is greater in plan size than the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 has a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with, for example, separately machined pins. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In Embodiment 1, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (270 mm in Embodiment 1) when the diameter of the semiconductor wafer W is 300 mm. Each of the substrate support pins 77 is made of quartz. The substrate support pins 77 may be welded on the upper surface of the holding plate 75, or machined integrally with the holding plate 75.

Referring again to FIG. 2, the four coupling portions 72 mounted upright on the base ring 71 are rigidly secured to the peripheral portion of the holding plate 75 of the susceptor 74 by welding. In other words, the susceptor 74 and the base ring 71 are fixedly coupled to each other with the coupling portions 72. The base ring 71 of the holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the susceptor 74 coincides with a vertical direction). In other words, the holding surface 75a of the holding plate 75 becomes a horizontal surface.

The semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (a distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75. The opening 78 is provided for the lower radiation thermometer 20 to receive light (infrared light) radiated from the lower surface of the semiconductor wafer W. Specifically, the lower radiation thermometer 20 receives the light emitted from the lower surface of the semiconductor wafer W through the opening 78 and the transparent window 21 mounted to the through hole 61b in the chamber side portion 61 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer the semiconductor wafer W.

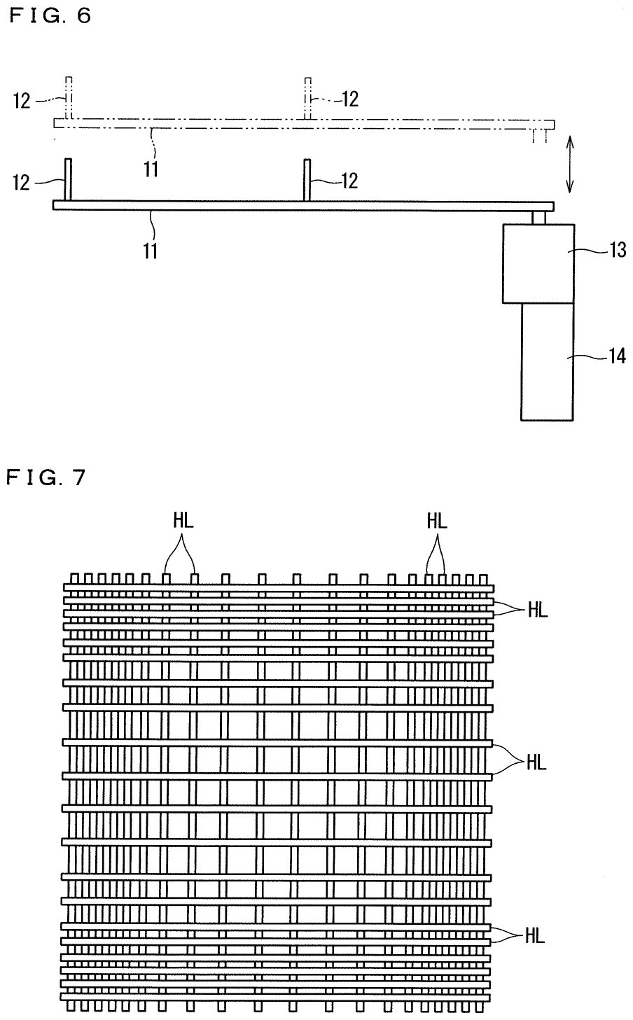

FIG. 5 is a plan view of the transfer mechanism 10. FIG. 6 is a side view of the transfer mechanism 10. The transfer mechanism 10 includes two transfer arms 11. The transfer arms 11 have an arcuate shape to fit the recessed portion 62 that is roughly annular. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 horizontally moves the pair of transfer arms 11 between a transfer operation position (a position indicated by solid lines in FIG. 5) in which the semiconductor wafer W is transferred to and from the holder 7 and a retracted position (a position indicated by dash-double-dot lines in FIG. 5) in which the transfer arms 11 do not overlap the semiconductor wafer W held by the holder 7 in a plan view. The horizontal movement mechanism 13 may cause individual motors to pivot the respective transfer arms 11. Alternatively, a linkage mechanism may cause a single motor to pivot the pair of transfer arms 11 in a cooperative manner.

The pair of transfer arms 11 is moved upward and downward by an elevating mechanism 14 together with the horizontal movement mechanism 13. When the elevating mechanism 14 moves up the pair of transfer arms 11 at the transfer operation position, the four lift pins 12 in total pass through the respective four through holes 79 (see FIGS. 2 and 3) bored in the susceptor 74 so that the upper ends of the lift pins 12 protrude from the upper surface of the susceptor 74. On the other hand, when the elevating mechanism 14 moves down the pair of transfer arms 11 at their transfer operation position to take the lift pins 12 out of the respective through holes 79 and the horizontal movement mechanism 13 moves the pair of transfer arms 11 to be opened, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not illustrated is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Referring again to FIG. 1, the chamber 6 includes two radiation thermometers (pyrometers in Embodiment 1) of the upper radiation thermometer 25 and the lower radiation thermometer 20. The upper radiation thermometer 25 is provided obliquely above the semiconductor wafer W held by the susceptor 74, and measures the temperature of the upper surface of the semiconductor wafer W by receiving the infrared light radiated from the upper surface of the semiconductor wafer W. The infrared sensor 29 of the upper radiation thermometer 25 includes an optical element made of InSb (indium antimonide) so as to be able to respond to rapid changes in temperature of the upper surface of the semiconductor wafer W at the moment of emission of a flash of light. On the other hand, the lower radiation thermometer 20 is provided obliquely below the semiconductor wafer W held by the susceptor 74, and measures the temperature of the lower surface of the semiconductor wafer W by receiving the infrared light radiated from the lower surface of the semiconductor wafer W.

The flash heater 5 provided over the chamber 6 includes, inside an enclosure 51, a light source including the multiple (30 in Embodiment 1) xenon flash lamps FL, and a reflector 52 to cover the upper portion of the light source. The flash lamps FL emit flashes of light to the semiconductor wafers W held by the holders 7. The flash heater 5 further includes a lamp light radiation window 53 mounted to the bottom of the enclosure 51. The lamp light radiation window 53 forming the floor of the flash heater 5 is a plate-like quartz window made of quartz. The flash heater 5 is provided over the chamber 6, whereby the lamp light radiation window 53 is opposed to the top chamber window 63. The flash lamps FL emit flashes of light to the heat treatment space 65 from over the chamber 6 through the lamp light radiation window 53 and the top chamber window 63.

The plurality of flash lamps FL, each of which is a rod-shaped lamp having an elongated cylindrical shape, are arranged in a plane so that the longitudinal directions of the respective flash lamps FL are in parallel with each other along the main surface of the semiconductor wafer W held by the holder 7 (that is, in a horizontal direction). Thus, a plane defined by the arrangement of the flash lamps FL is also a horizontal plane.

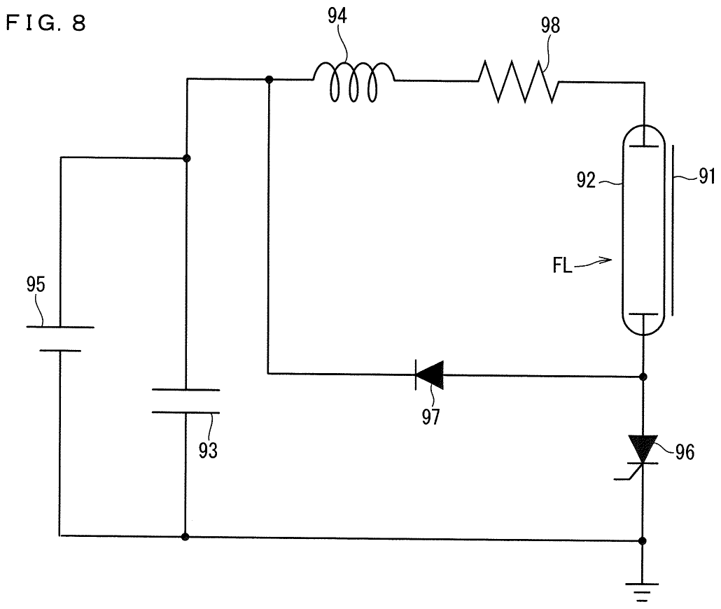

FIG. 8 illustrates a discharge circuit of the flash lamp FL according to Embodiment 1. This discharge circuit allows a current to flow through the flash lamp FL and causes the flash lamp FL to emit light. As illustrated in FIG. 8, a capacitor 93, a coil 94, the flash lamp FL, and a gate commutated turn-off (GCT) thyristor 96 are connected in series with each other. In other words, the GCT thyristor 96 is connected in series with the flash lamp FL in Embodiment 1.

The flash lamp FL includes a rod-shaped glass tube (discharge tube) 92 containing a xenon gas sealed therein and having positive and negative electrodes on opposite ends thereof, and a trigger electrode 91 attached to the outer peripheral surface of the glass tube 92. A power source unit 95 applies a predetermined voltage to the capacitor 93 into which charges corresponding to the applied voltage (a charged voltage) are charged. Furthermore, a trigger circuit that is not illustrated can apply a high voltage to the trigger electrode 91. The controller 3 controls the timing with which the voltage is applied to the trigger electrode 91.

The coil 94 is a passive element that resists, when a discharge circuit is subjected to abrupt changes in current, the change. In FIG. 8, the flash lamp FL is connected in series with a floating resistor 98. The floating resistor 98 is not provided as an element, but is a resistor inevitably occurring in a circuit.

The GCT thyristor 96 is a thyristor obtained by improving a gate of a gate turn-off (GTO) thyristor. Thus, the GCT thyristor 96 has a self-extinguishing function of transitioning from an ON state to an OFF state when a negative signal is supplied to its gate similarly to the GTO thyristor. Furthermore, the GCT thyristor 96 has a function of transitioning from an OFF state to an ON state when a positive signal is supplied to its gate, as a basic function of the thyristor. In other words, the GCT thyristor 96 is turned on or off according to a signal to be supplied to the gate. Turning on or off the GCT thyristor 96 turns on or off the current flowing through the flash lamp FL. Furthermore, the GCT thyristor 96 has advanced in increasing its withstand voltage and its current. Thus, a voltage higher than or equal to 6000 V can be applied to the GCT thyristor 96, and a current up to 6000 A can flow through the GCT thyristor 96.

Even when a high voltage is applied across electrodes of the glass tube 92 during the ON state of the GCT thyristor 96 with the capacitor 93 being charged, no electricity flows through the glass tube 92 in a normal state. This is because the xenon gas is an electrically insulator. However, when a high voltage is applied to the trigger electrode 91 to cause an electrical breakdown, the discharge between the electrodes momentarily allows the current to flow through the glass tube 92. Here, excitation of xenon atoms or molecules causes light to be emitted.

Since the GCT thyristor 96 is connected in series with the flash lamp FL in Embodiment 1, the abrupt changes in current creates a coil surge that instantaneously applies a high voltage to the coil 94 in an opposite direction at the moment when the GCT thyristor 96 enters an OFF state. Such a high voltage caused by the coil surge may unfortunately damage other circuit elements. Thus, the discharge circuit according to Embodiment 1 includes a flyback diode 97 that absorbs the high voltage caused by the coil surge, as illustrated in FIG. 8. This flyback diode 97 protects the elements in the discharge circuit from the coil surge.

The discharge circuit illustrated in FIG. 8 is provided for each of the flash lamps FL included in the flash heater 5. Since the 30 flash lamps FL are arranged in the plane in Embodiment 1, 30 discharge circuits each illustrated in FIG. 8 are provided to correspond to the flash lamps FL. Thus, the GCT thyristor 96 individually turns ON or OFF the current that flows through a corresponding one of the 30 flash lamps FL.

Referring again to FIG. 1, the reflector 52 is provided over the plurality of flash lamps FL to cover all of the flash lamps FL. The basic function of the reflector 52 is to reflect the flash of light emitted from the plurality of flash lamps FL to the heat treatment space 65 side. The reflector 52 is a plate made of an aluminum alloy. A surface of the reflector 52 (a surface which faces the flash lamps FL) is roughened by abrasive blasting.

The halogen heater 4 provided under the chamber 6 includes, inside an enclosure 41, the multiple (40 in Embodiment 1) halogen lamps HL. The halogen heater 4 is a light emitter that emits light to the heat treatment space 65 from under the chamber 6 through the bottom chamber window 64 to heat the semiconductor wafer W by means of the halogen lamps HL.

FIG. 7 is a plan view showing an arrangement of the multiple halogen lamps HL. The 40 halogen lamps HL are arranged in two tiers, i.e. upper and lower tiers. That is, 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape. The 20 halogen lamps HL in each of the upper tier and the lower tier are arranged so that the longitudinal directions thereof are in parallel with each other along the main surface of the semiconductor wafer W held by the holder 7 (that is, in a horizontal direction). Thus, a plane defined by the arrangement of the halogen lamps HL in each of the upper and lower tiers is a horizontal plane.

As shown in FIG. 7, the halogen lamps HL in each of the upper and lower tiers are disposed at a higher density in a region facing the peripheral portion of the semiconductor wafer W held by the holder 7 than in a region facing the central portion thereof. In other words, the halogen lamps HL in each of the upper and lower tiers are arranged at shorter intervals in the peripheral portion of the lamp arrangement than in the central portion thereof. When the semiconductor wafer W is heated by the halogen heater 4 through light emission, a greater amount of light can impinge upon the peripheral portion of the semiconductor wafer W subject to a temperature decrease.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (e.g., iodine or bromine) in trace amounts into an inert gas such as nitrogen or argon is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. In other words, the halogen lamps HL are continuous lighting lamps that emit light continuously for not less than one second. In addition, the halogen lamps HL, which are rod-shaped lamps, have a long life. The arrangement of the halogen lamps HL in a horizontal direction exhibits superior radiation efficiency toward the semiconductor wafer W provided over the halogen lamps HL.

A reflector 43 is provided also inside the enclosure 41 of the halogen heater 4 under the halogen lamps HL arranged in two tiers (FIG. 1). The reflector 43 reflects the light emitted from the plurality of halogen lamps HL toward the heat treatment space 65.

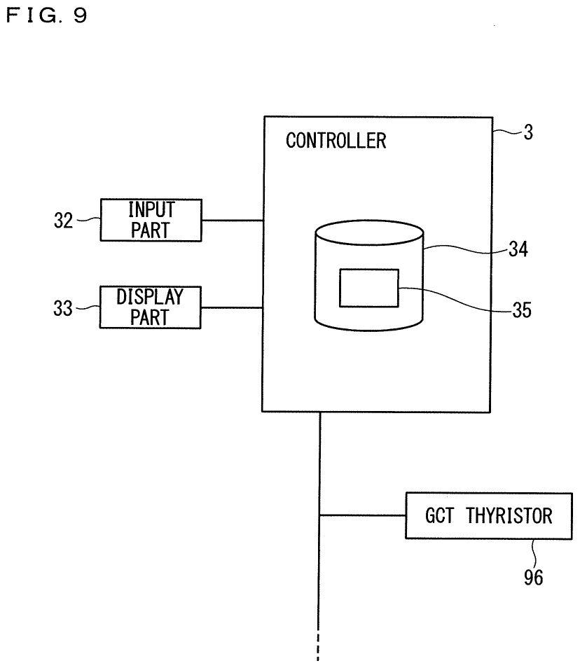

The controller 3 controls the aforementioned various operating mechanisms provided in the heat treatment apparatus 1. FIG. 9 is a block diagram illustrating a configuration of the controller 3. The controller 3 is similar in hardware configuration to a typical computer. Specifically, the controller 3 includes a CPU that is a circuit for performing various computation processes, a ROM or read-only memory for storing a basic program, a RAM or readable/writable memory for storing various pieces of information, and a storage 34 (e.g., a magnetic disk) for storing, for example, control software and data. The CPU in the controller 3 executes a predetermined processing program, whereby the processes in the heat treatment apparatus 1 proceed.

The storage 34 of the controller 3 stores a treatment recipe 35 defining procedures and conditions for treating the semiconductor wafer W. The heat treatment apparatus 1 obtains the treatment recipe 35, for example, fed and stored in the storage 34 by an operator of this apparatus through an input part 32 to be described later. Alternatively, the treatment recipe 35 may be stored in the storage 34 after a host computer that manages a plurality of heat treatment apparatuses 1 passes the treatment recipe 35 to the heat treatment apparatus 1 through communication.

The controller 3 is electrically connected to the elements including the GCT thyristor 96. The controller 3 controls the discharge circuits of the flash lamps FL, for example, according to the details of the treatment recipe 35. Specifically, the controller 3 controls a signal to be supplied to the gate of the GCT thyristor 96 so that the GCT thyristor 96 switches between an ON state (a conductive state) and an OFF state (a blocking state).

The controller 3 is connected to a display part 33 and the input part 32. The display part 33 and the input part 32 function as a user interface of the heat treatment apparatus 1. The controller 3 displays a variety of pieces of information on the display part 33. An operator of the heat treatment apparatus 1 can input various commands and parameters from the input part 32 while viewing the information displayed on the display part 33. A keyboard and a mouse, for example, may be used as the input part 32. A liquid crystal display, for example, may be used as the display part 33. In Embodiment 1, a liquid crystal touch panel provided on an outer wall of the heat treatment apparatus 1 is used to function as both the display part 33 and the input part 32.

The heat treatment apparatus 1 further includes, in addition to the aforementioned components, various cooling structures to prevent an excessive temperature rise in the halogen heater 4, the flash heater 5, and the chamber 6 due to the heat energy generated from the halogen lamps HL and the flash lamps FL during the heat treatment of the semiconductor wafer W. For example, a water cooling tube (not illustrated) is provided in the walls of the chamber 6. Also, the halogen heater 4 and the flash heater 5 have an air cooling structure for generating a gas flow therein to exhaust heat. Air is supplied to a gap between the top chamber window 63 and the lamp light radiation window 53 to cool down the flash heater 5 and the top chamber window 63.

Next, a treatment operation in the heat treatment apparatus 1 will be described. The semiconductor wafer W to be treated is a semiconductor substrate to which impurities (ion) are applied by an ion implantation method. The impurities are activated by the heat treatment apparatus 1 in flash-of-light emission and heating processes (annealing). The controller 3 controls the operating mechanisms provided in the heat treatment apparatus 1, so that the operating procedure in the heat treatment apparatus 1 to be described later will proceed.

The valve 84 for supply of gas is opened, and the valves 89 and 192 for exhaust of gas are opened, so that the supply and exhaust of gas into and out of the chamber 6 start. When the valve 84 is opened, nitrogen gas is supplied into the heat treatment space 65 through the gas supply opening 81. When the valve 89 is opened, the gas within the chamber 6 is exhausted through the gas exhaust opening 86. This causes the nitrogen gas supplied from an upper portion of the heat treatment space 65 in the chamber 6 to flow downward and then to be exhausted from a lower portion of the heat treatment space 65.

The gas within the chamber 6 is exhausted also through the transport opening 66 by opening the valve 192. Further, the exhaust mechanism not illustrated exhausts an atmosphere near the drivers of the transfer mechanism 10. The nitrogen gas is continuously supplied into the heat treatment space 65 during the heat treatment of the semiconductor wafer W in the heat treatment apparatus 1. The amount of nitrogen gas supplied into the heat treatment space 65 is changed as appropriate in accordance with process steps.

Subsequently, the gate valve 185 is opened to open the transport opening 66. A transport robot outside the heat treatment apparatus 1 transports the semiconductor wafer W to be treated into the heat treatment space 65 of the chamber 6 through the transport opening 66. At this time, there is a danger that an atmosphere outside the heat treatment apparatus 1 is carried into the heat treatment space 65 as the semiconductor wafer W is transported. However, the nitrogen gas is continuously supplied into the chamber 6. Thus, the nitrogen gas flows out of the transport opening 66 to minimize the outside atmosphere carried into the heat treatment space 65.

The semiconductor wafer W transported by the transport robot is moved forward to a position lying immediately over the holder 7 and is stopped. Then, the pair of transfer arms 11 of the transfer mechanism 10 is moved horizontally from the retracted position to the transfer operation position and is then moved upward, whereby the lift pins 12 pass through the through holes 79 and protrude from the upper surface of the holding plate 75 of the susceptor 74 to receive the semiconductor wafer W. At this time, the lift pins 12 move upward above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downward to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 on a front surface on which patterns have been formed and into which impurities have been implanted, as an upper surface. The back surface (a main surface opposite to the front surface) of the semiconductor wafer W supported by the substrate support pins 77 is spaced a predetermined distance apart from the holding surface 75a of the holding plate 75. The pair of transfer arms 11 moved downward below the susceptor 74 is moved back to the retracted position, i.e. to the inside of the recessed portion 62, by the horizontal movement mechanism 13.

After the semiconductor wafer W is held from below in a horizontal attitude by the susceptor 74 of the holder 7 made of quartz, the 40 halogen lamps HL in the halogen heater 4 are simultaneously turned on to start preheating (assist-heating). The halogen light emitted from the halogen lamps HL is transmitted through the bottom chamber window 64 and the susceptor 74 both made of quartz, and impinges upon the lower surface of the semiconductor wafer W. By receiving light emitted from the halogen lamps HL, the semiconductor wafer W is preheated, so that the temperature of the semiconductor wafer W increases. The transfer arms 11 of the transfer mechanism 10, which are retracted to the inside of the recessed portion 62, do not become an obstacle to the heating using the halogen lamps HL.

The temperature of the semiconductor wafer W is measured by the lower radiation thermometer 20 when the halogen lamps HL perform the preheating. Specifically, the lower radiation thermometer 20 measures the temperature of the wafer at elevated temperatures by receiving, through the transparent window 21, the infrared light radiated through the opening 78 from the lower surface of the semiconductor wafer W held by the susceptor 74. The measured temperature of the semiconductor wafer W is transmitted to the controller 3. The controller 3 controls the output from the halogen lamps HL while monitoring whether the temperature of the semiconductor wafer W, which will be increased by emission of light from the halogen lamps HL, reaches a predetermined preheating temperature T1. In other words, the controller 3 provides, based on a measurement value of the lower radiation thermometer 20, feedback control of the output from the halogen lamps HL so that the temperature of the semiconductor wafer W is equal to the preheating temperature T1. Thus, the lower radiation thermometer 20 is a radiation thermometer for controlling the temperature of the semiconductor wafer W in preheating the semiconductor wafer W. The preheating temperature T1 approximately ranges from 200° C. to 800° C., preferably, from 350° C. to 600° C. (400° C. in Embodiment 1) in which no impurity applied to the semiconductor wafer W may be diffused by heat.

After the temperature of the semiconductor wafer W reaches the preheating temperature T1, the controller 3 tentatively maintains the semiconductor wafer W at the preheating temperature T1. Specifically, the controller 3 adjusts the output from the halogen lamps HL when the temperature of the semiconductor wafer W measured by the lower radiation thermometer 20 reaches the preheating temperature T1, to maintain the temperature of the semiconductor wafer W almost at the preheating temperature T1.

By performing such preheating using the halogen lamps HL, the temperature of the entire semiconductor wafer W is uniformly increased to the preheating temperature T1. Since the temperature of the peripheral portion of the semiconductor wafer W from which heat is more easily dissipated tends to decrease more than that of the central portion thereof in the preheating phase using the halogen lamps HL, the halogen lamps HL in the halogen heater 4 are disposed at a higher density in a region facing the peripheral portion of the semiconductor wafer W than that in a region facing the central portion thereof. This allows a greater amount of light to impinge upon the peripheral portion of the semiconductor wafer W from which heat is easily dissipated, and allows the plane temperature distribution of the semiconductor wafer W in the preheating phase to be uniform.

The flash lamps FL emit flashes of light to the front surface of the semiconductor wafer W after a lapse of a predetermined time period since the temperature of the semiconductor wafer W reaches the preheating temperature T1. A part of the flashes of light emitted from the flash lamps FL is directly directed into the chamber 6, and another part thereof is temporarily reflected by the reflector 52 and then directed into the chamber 6. These radiated flashes of light initiate flash heating of the semiconductor wafer W.

For the emission of the flashes of light from the flash lamps FL, the power source unit 95 applies, in advance, a predetermined charged voltage to the capacitor 93 to accumulate the charges in the capacitor 93. An amount of the charges accumulated into the capacitor 93 is defined by a product of the capacitance C of the capacitor 93 and the voltage V charged by the power source unit 95.

While the charges are accumulated into the capacitor 93, a positive signal supplied to the gate of the GCT thyristor 96 through the control of the controller 3 sets the GCT thyristor 96 to an ON state. Through this control of the controller 3, a high voltage (a trigger voltage) is applied to the trigger electrode 91 simultaneously with the timing with which the GCT thyristor 96 is turned ON. When the GCT thyristor 96 is set to the ON state with the charges being accumulated in the capacitor 93 and a high voltage is applied to the trigger electrode 91 simultaneously with the timing with which the GCT thyristor 96 is turned ON, a current flows across the electrodes of the glass tube 92. Here, excitation of xenon atoms or molecules causes light to be emitted and causes the flash lamps FL to emit flashes of light. Accordingly, the 30 flash lamps FL of the flash heater 5 emit flashes of light to the front surface of the semiconductor wafer W held by the holder 7 to heat the front surface of the semiconductor wafer W.

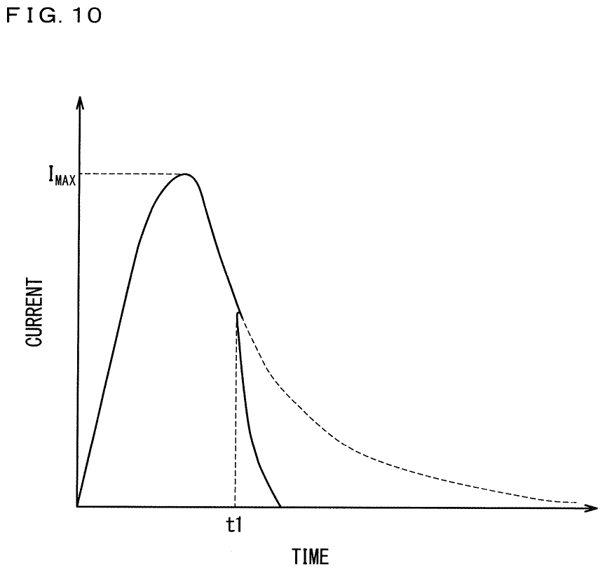

FIG. 10 illustrates a current flowing through the flash lamps FL according to Embodiment 1. The current starts to flow through the flash lamp FL simultaneously when the GCT thyristor 96 enters an ON state. The waveform of the current flowing through the flash lamp FL while the GCT thyristor 96 is in the ON state is defined by, for example, the capacitance C of the capacitor 93, the inductance L of the coil 94, and the charged voltage V. In Embodiment 1, the maximum value I_{MAX} of the current flowing through the flash lamps FL is approximately 4000 A.

In Embodiment 1, at the time t1 after a lapse of 0.1 millisecond since the GCT thyristor 96 enters the ON state and the current starts to flow through the flash lamp FL, a negative signal supplied to the gate of the GCT thyristor 96 through the control of the controller 3 sets the GCT thyristor 96 to an OFF state. Setting the GCT thyristor 96 to the OFF state forcibly blocks a discharge current flowing through the flash lamp FL, and stops the emission of the flash lamp FL.

A dotted line after the time t1 in FIG. 10 is a waveform of the current flowing through the flash lamp FL when the flash lamp FL is caused to emit light without the GCT thyristor 96. As illustrated by the dotted line in FIG. 10, the current flowing through the flash lamp FL is never forcibly blocked in the absence of the GCT thyristor 96. Thus, a tail current continues to flow for a relatively long time period. Thus, the front surface of the semiconductor wafer W continues to be heated after the time t1. This reduces the cooling rate of the semiconductor wafer W after emission of the flash of light, and impairs lowering the heat history.

A solid line after the time t1 in FIG. 10 illustrates a change in the current when the GCT thyristor 96 enters an OFF state in Embodiment 1. Forcibly blocking the current flowing through the flash lamp FL after the GCT thyristor 96 enters the OFF state can suppress the tail current more significantly than that indicated by the dotted line in FIG. 10. Thus, the semiconductor wafer W after the time t1 at which the GCT thyristor 96 enters the OFF state is hardly heated. Thereby, the total heat charged into the semiconductor wafer W can be reduced, and the annealing with the low heat history can be implemented. Furthermore, the cooling rate of the semiconductor wafer W after the time t1 can be increased.

However, when the GCT thyristor 96 enters the OFF state in Embodiment 1, the abrupt changes in current may create a coil surge that instantaneously applies a high voltage to the coil 94 in an opposite direction. Thus, the discharge circuit according to Embodiment 1 includes the flyback diode 97 that absorbs the high voltage caused by the coil surge (FIG. 8). Although the flyback diode 97 can protect the elements in the discharge circuit from the coil surge, a small tail current remains as illustrated in FIG. 10. This is because the current caused by the voltage generated in the coil 94 even after the GCT thyristor 96 enters the OFF state flows through the flyback diode 97 and the flash lamp FL.

Through emission of light from the flash lamps FL which is caused by the flow of the current having the waveform as illustrated in FIG. 10, the flash lamps FL emit flashes of light to the front surface of the semiconductor wafer W for approximately 0.1 millisecond of the emission time. Then, the temperature of the front surface is instantaneously increased to the treatment temperature T2, and is rapidly cooled. The treatment temperature T2 is 1000° C. in Embodiment 1. Specifically, instantaneously feeding a maximum current as large as 4000 A to the flash lamps FL causes the flash lamps FL to emit flashes of light to the front surface of the semiconductor wafer W for an emission time of approximately 0.1 millisecond to increase the temperature of the front surface to approximately 600° C. in Embodiment 1. This allows activation of impurities implanted into the semiconductor wafer W while diffusion of the impurities caused by the heat of the impurities is suppressed.

After a lapse of a predetermined time period since supply of the current to the flash lamps FL is stopped, the halogen lamps HL are turned off. This rapidly lowers the temperature of the semiconductor wafer W from the preheating temperature T1. The lower radiation thermometer 20 measures the temperature of the semiconductor wafer W which is on the decrease. The result of measurement is transmitted to the controller 3. The controller 3 monitors whether the temperature of the semiconductor wafer W is lowered to a predetermined temperature, based on the result of measurement of the lower radiation thermometer 20. After the temperature of the semiconductor wafer W is lowered to the predetermined temperature or below, the pair of transfer arms 11 of the transfer mechanism 10 is moved horizontally again from the retracted position to the transfer operation position and is then moved upward, so that the lift pins 12 protrude from the upper surface of the susceptor 74 to receive the heat-treated semiconductor wafer W from the susceptor 74. Subsequently, the transport opening 66 closed by the gate valve 185 is opened, and the transport robot outside the heat treatment apparatus 1 transports the semiconductor wafer W placed on the lift pins 12 to the outside. Thus, the heat treatment apparatus 1 completes the heat treatment of the semiconductor wafer W.

In Embodiment 1, the flash lamp FL is connected in series with the GCT thyristor 96. After a lapse of a predetermined time period since a current starts to flow through the flash lamp FL, the GCT thyristor 96 enters the OFF state and forcibly blocks the current flowing through the flash lamp FL. This can suppress the tail current flowing through the flash lamp FL. As a result, the total heat charged into the semiconductor wafer W can be reduced, and the annealing with the low heat history can be implemented while the cooling rate of the semiconductor wafer W is increased. Implementation of the low heat history with the cooling rate of the semiconductor wafer W being increased can prevent deactivation of the impurities.

Feeding the current as large as 4000 A to the flash lamp FL and setting the emission time of the flash lamp FL to an extremely short time of 0.1 millisecond in the absence of the GCT thyristor 96 require reducing the capacitance C of the capacitor 93 and increasing the charged voltage V to a very high voltage. As described above, increasing the charged voltage V shortens the life of the flash lamps FL.

Since the GCT thyristor 96 forcibly blocks the current flowing through the flash lamp FL in Embodiment 1, the emission time of the flash lamp FL can be set to 0.1 millisecond while the capacitance C of the capacitor 93 is increased. As long as the capacitance C of the capacitor 93 can be increased, the energy required for feeding the current as large as 4000 A to the flash lamp FL can be charged into the flash lamp FL while the charged voltage V is reduced. Reduction in the charged voltage V can prevent the life of the flash lamps FL from being shortened.

Furthermore, the GCT thyristor 96 in Embodiment 1 is disposed at the position identical to that of the IGBT in the circuit disclosed in each of Patent Documents 1 and 2. This means that replacing the IGBT in the discharge circuit of the conventional heat treatment apparatus with the GCT thyristor results in obtainment of the heat treatment apparatus according to the present invention without changing the other circuit elements.

Although the GCT thyristor 96 enters an OFF state after a lapse of 0.1 millisecond since a current starts to flow through the flash lamp FL in Embodiment 1, the recipe 35 can designate the timing with which the GCT thyristor 96 enters the OFF state. The controller 3 sets the GCT thyristor 96 to an OFF state after a lapse of the time designated by the recipe 35 since the current starts to flow through the flash lamp FL. Thus, changing the details of the recipe 35 can set the time from start of the current flowing through the flash lamp FL to the OFF state of the GCT thyristor 96, shorter or longer than 0.1 millisecond.

After the GCT thyristor 96 enters the OFF state, non-consumed charges remain in the capacitor 93 in Embodiment 1. Thus, the time for recharging the capacitor 93 for the next emission of a flash of light can be shortened. Consequently, the throughput of the heat treatment apparatus 1 can be increased.

### Embodiment 2

Embodiment 2 according to the present invention will be described next. An overall structure of a heat treatment apparatus according to Embodiment 2 is almost the same as that according to Embodiment 1 (FIG. 1). Furthermore, the procedure for treating the semiconductor wafer W in Embodiment 2 is almost the same as that according to Embodiment 1. Although the GCT thyristor 96 is connected in series with the flash lamp FL in Embodiment 1, a GCT thyristor is connected in parallel with the flash lamp FL in Embodiment 2.

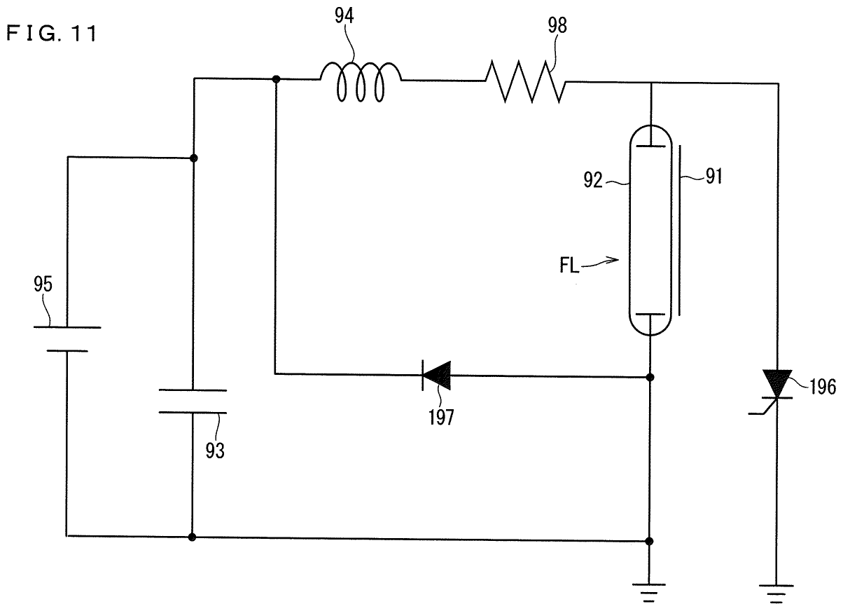

FIG. 11 illustrates a discharge circuit of the flash lamp FL according to Embodiment 2. In FIG. 11, the same reference numerals are attached to the same elements as those in Embodiment 1 (FIG. 8). This discharge circuit in FIG. 11 allows a current to flow through the flash lamp FL and causes the flash lamp FL to emit light in Embodiment 2. As illustrated in FIG. 11, the capacitor 93, the coil 94, and the flash lamp FL are connected in series with each other. Furthermore, a GCT thyristor 196 is connected in parallel with the flash lamp FL in Embodiment 2.

The discharge circuit in FIG. 11 does not require a flyback diode because no coil surge occurs even when the GCT thyristor 196 enters an OFF state. The discharge circuit in FIG. 11, however, includes an oscillation-proof diode 197 because the GCT thyristor 196 entering an ON state may oscillate depending on a circuit constant. The rest of the structure of Embodiment 2 except for connecting the GCT thyristor 196 in parallel with the flash lamp FL and including the oscillation-proof diode 197 is identical to that of Embodiment 1.

For emission of flashes of light from the flash lamps FL in Embodiment 2, the power source unit 95 applies, in advance, a predetermined charged voltage to the capacitor 93 to accumulate the charges in the capacitor 93. Application of a high voltage to the trigger electrode 91 through the control of the controller 3 with the charges being accumulated in the capacitor 93 starts emission of light from the flash lamps FL, so that the flash lamps FL radiate flashes of light. The flashes of light are emitted from the flash lamps FL to the front surface of the semiconductor wafer W. Accordingly, the semiconductor wafer W is heated.

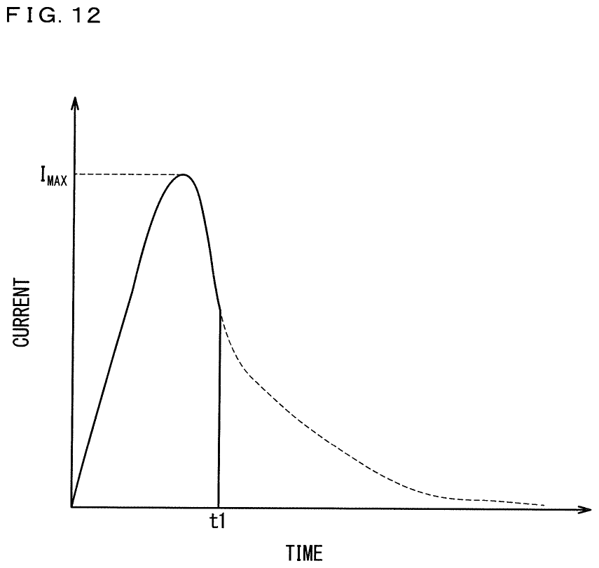

FIG. 12 illustrates a current flowing through the flash lamps FL according to Embodiment 2. The current starts to flow through the flash lamp FL simultaneously when a high voltage is applied to the trigger electrode 91 in Embodiment 2. Here, the GCT thyristor 196 is in an OFF state. The waveform of the current flowing through the flash lamp FL while the GCT thyristor 196 is in the OFF state is defined by, for example, the capacitance C of the capacitor 93, the inductance L of the coil 94, and the charged voltage V. In Embodiment 2, the maximum value I_{MAX} of the current flowing through the flash lamps FL is also approximately 4000 A.

In Embodiment 2, at the time t1 after a lapse of 0.1 millisecond since the current starts to flow through the flash lamp FL, a positive signal supplied to the gate of the GCT thyristor 196 through the control of the controller 3 sets the GCT thyristor 196 to an ON state. Setting the GCT thyristor 196 to the ON state allows a discharge current flowing through the flash lamp FL to flow through the GCT thyristor 196 with a smaller impedance. This prevents the current from flowing through the flash lamps FL, and stops emission of light from the flash lamps FL.

A dotted line after the time t1 in FIG. 12 is a waveform of the current flowing through the flash lamp FL when the flash lamp FL is caused to emit light in the absence of the GCT thyristor 196 similarly to FIG. 10. As illustrated by the dotted line in FIG. 12, a tail current continues to flow through the flash lamp FL for a relatively long time period in the absence of the GCT thyristor 196.

A solid line at the time t1 in FIG. 12 illustrates a change in the current when the GCT thyristor 196 enters an ON state. Preventing the current from flowing through the flash lamp FL by setting the GCT thyristor 196 to the ON state can suppress the tail current more significantly than that indicated by the dotted line in FIG. 12. Thus, the semiconductor wafer W after the time t1 at which the GCT thyristor 196 enters the ON state is hardly heated. Thereby, the total heat charged into the semiconductor wafer W can be reduced, and the annealing with the low heat history can be implemented. Furthermore, the cooling rate of the semiconductor wafer W after the time t1 can be increased.

Since no flyback diode is provided in Embodiment 2, the tail current can be completely cut as illustrated in FIG. 12. Although the oscillation-proof diode 197 that prevents the GCT thyristor 196 entering an ON state from oscillating is provided in Embodiment 2, this oscillation-proof diode 197 does not influence the waveform of the current.

With the flow of the current having the waveform as illustrated in FIG. 12, the flash lamps FL emit flashes of light to the front surface of the semiconductor wafer W for approximately 0.1 millisecond of the emission time. Then, the temperature of the front surface is instantaneously increased to the treatment temperature T2, and is rapidly cooled. The treatment temperature T2 is 1000° C. in Embodiment 2. Specifically, instantaneously feeding a maximum current as large as 4000 A to the flash lamps FL also in Embodiment 2 causes the flash lamps FL to emit flashes of light to the front surface of the semiconductor wafer W for an emission time of approximately 0.1 millisecond to increase the temperature of the front surface to approximately 600° C.

In Embodiment 2, the GCT thyristor 196 is connected in parallel with the flash lamp FL. After a lapse of a predetermined time period since a current starts to flow through the flash lamp FL, the GCT thyristor 196 enters the ON state and stops the current flowing through the flash lamp FL. This can suppress the tail current flowing through the flash lamps FL. As a result, the total heat charged into the semiconductor wafer W can be reduced, and the annealing with the low heat history can be implemented while the cooling rate of the semiconductor wafer W is increased.

Particularly, comparison between FIG. 10 and FIG. 12 clarifies that a small tail current remains in Embodiment 1, whereas the tail current can be completely eliminated in Embodiment 2. Thus, the annealing with the lower heat history can be implemented in Embodiment 2.

Since the GCT thyristor 196 prevents the current from flowing through the flash lamp FL in Embodiment 2, the emission time of the flash lamp FL can be set to 0.1 millisecond even with the capacitance C of the capacitor 93 being increased. As long as the capacitance C of the capacitor 93 can be increased, the energy required for feeding the current as large as 4000 A to the flash lamp FL can be charged into the flash lamp FL while the charged voltage V is reduced. Reduction in the charged voltage V can prevent the life of the flash lamps FL from being shortened.

Embodiment 2 requires sufficiently reducing the impedance of the GCT thyristor 196 more than that of the flash lamp FL. Thus, a cable to be connected to the GCT thyristor 196 needs to be shortened as much as possible to reduce the impedance. Compared to Embodiment 1, there is a constraint on the position of the GCT thyristor 196 in Embodiment 2.

In Embodiment 2 where the GCT thyristor 196 is connected in parallel with the flash lamp FL, a current exceeding the rated current (a current exceeding 6000 A) may flow through the GCT thyristor 196, depending on the timing with which the GCT thyristor 196 enters an ON state. Although the recipe 35 can freely designate the timing with which the GCT thyristor 96 enters an OFF state in Embodiment 1, the timing with which the GCT thyristor 196 enters an ON state is restricted in Embodiment 2.

Furthermore, since a current flows through the GCT thyristor 196 set to the ON state, all the charges accumulated in the capacitor 93 are to be consumed. In other words, no charge remains in the capacitor 93. Thus, the time for recharging the capacitor 93 for the next emission of a flash of light is longer than that in Embodiment 1.

### Embodiment 3

Embodiment 3 according to the present invention will be described next. An overall structure of a heat treatment apparatus according to Embodiment 3 is almost the same as that according to Embodiment 1 (FIG. 1). Furthermore, the procedure for treating the semiconductor wafer W in Embodiment 3 is almost the same as that according to Embodiment 1. In Embodiment 3, two GCT thyristors are connected in series and parallel with the flash lamp FL.

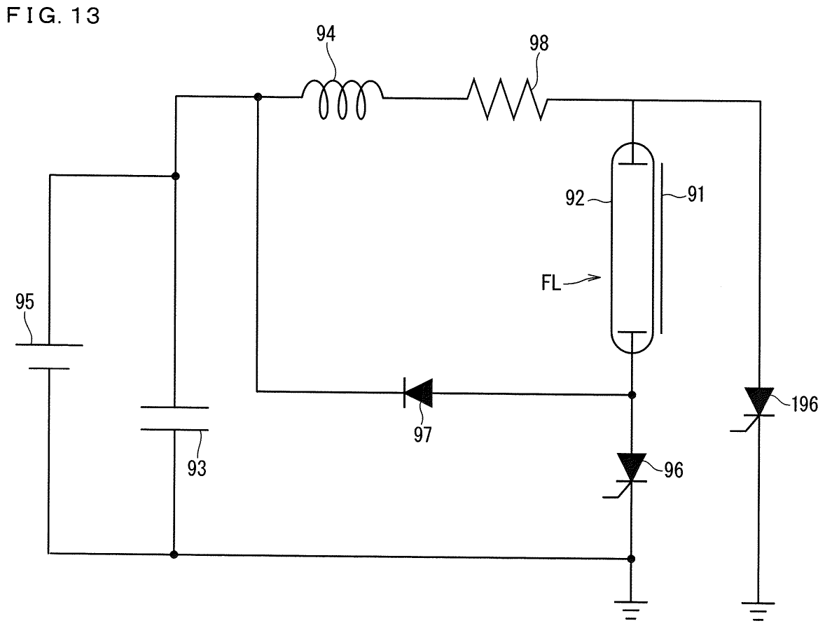

FIG. 13 illustrates a discharge circuit of the flash lamp FL according to Embodiment 3. In FIG. 13, the same reference numerals are attached to the same elements as those in Embodiment 1 (FIG. 8) and Embodiment 2 (FIG. 11). The discharge circuit according to Embodiment 3 has a structure obtained by combining the structures in Embodiments 1 and 2. Specifically, the flash lamp FL is connected not only in series with the GCT thyristor 96 but also in parallel with the GCT thyristor 196 in Embodiment 3.

In Embodiment 3, the controller 3 selects which one of the GCT thyristors 96 and 196 operates, based on the designation of the recipe 35. When the controller 3 selects operation of the GCT thyristor 96 connected in series with the flash lamp FL, the same operations as those in Embodiment 1 are performed. Specifically, after a lapse of a predetermined time period since a current starts to flow through the flash lamp FL, the GCT thyristor 96 enters the OFF state and forcibly blocks the current flowing through the flash lamp FL.

When the controller 3 selects operation of the GCT thyristor 196 connected in parallel with the flash lamp FL, the same operations as those in Embodiment 2 are performed. Specifically, after a lapse of a predetermined time period since a current starts to flow through the flash lamp FL, the GCT thyristor 196 enters the ON state and stops the current flowing through the flash lamp FL. Embodiments 1 and 2 have respective advantages. In Embodiment 3, appropriate advantages can be selected and used according to a circumstance.

In Embodiment 3, the controller 3 can select and operate both of the GCT thyristors 96 and 196. Specifically, after a lapse of a predetermined time period since a current starts to flow through the flash lamp FL, the GCT thyristor 96 may enter an OFF state, and the GCT thyristor 196 may enter an ON state. This can suppress the tail current and prevent the life of the flash lamps FL from being shortened, similarly to Embodiments 1 and 2.

### MODIFICATION

While Embodiments according to the present invention are described above, various modifications of the present invention in addition to those described above may be made without departing from the scope and spirit of the invention. Although, for example, the GCT thyristor 196 is connected in parallel with the flash lamp FL in Embodiment 2, an IGBT may be connected in parallel with the flash lamp FL as a replacement for the GCT thyristor 196. In other words, a switching element that is turned on or off according to an input signal should be connected in parallel with the flash lamp FL. Similarly to Embodiment 2, after a lapse of a predetermined time period since a current starts to flow through the flash lamp FL, the switching element enters an ON state, and can stop the current flowing through the flash lamp FL and suppress the tail current. Obviously, it is preferred to apply a GCT thyristor as a switching element connected in parallel with the flash lamp FL. This is because at the moment when the switching element enters an ON state, a large current flows through the switching element.

In Embodiment 3, an IGBT may be connected in parallel with the flash lamp FL as a replacement for the GCT thyristor 196.

In Embodiment 3, an IGBT may also be connected in series with the flash lamp FL as a replacement for the GCT thyristor 96. A structure including an IGBT connected in series with a flash lamp FL and the GCT thyristor 196 connected in parallel with the flash lamp FL can be regarded as a structure in which the GCT thyristor 196 is further connected in parallel with each of the flash lamps FL in the conventional discharge circuits disclosed in Patent Documents 1 and 2. Although the conventional discharge circuits have tail currents of the order of milliseconds due to larger constants of capacitors and coils, connecting the GCT thyristor 196 in parallel with each of the flash lamps FL can completely cut the tail currents.

Furthermore, the timing with which the GCT thyristor 96 enters the OFF state is designated by the recipe 35 in Embodiment 1. The timing is not particularly limited to this, but may be set by an operator of this heat treatment apparatus 1 through the input part 32. In Embodiment 3, the operator of the heat treatment apparatus 1 may designate which one of the GCT thyristors 96 and 196 operates.

Although the flash heater 5 includes the 30 flash lamps FL in Embodiments, the number of the flash lamps FL is not limited to this but can be any. Furthermore, the flash lamps FL are not limited to xenon flash lamps but may be krypton flash lamps. The number of the halogen lamps HL included in the halogen heater 4 is not limited to 40 but can be any.

The filament-type halogen lamps HL preheat the semiconductor wafer W as continuous lighting lamps that emit light continuously for not less than one second in Embodiments. The continuous lighting lamps that preheat the semiconductor wafer W are not limited to the halogen lamps HL but may be discharge-type arc lamps (e.g., xenon arc lamps) or LED lamps as a replacement for the halogen lamps HL.

Furthermore, the heat treatment apparatus 1 may not only perform heat treatment for activating impurities, but also perform heat treatment on a gate insulating film with a high dielectric constant (a high-k film), bond a metal to silicon, or crystallize the polysilicon.

While the invention has been shown and described in detail, the foregoing description is in all aspects illustrative and not restrictive. It is therefore understood that numerous modifications and variations can be devised without departing from the scope of the invention.

What is claimed is:

1. A heat treatment apparatus that heats a substrate by emitting a flash of light to the substrate, the apparatus comprising:
a chamber housing the substrate;
a holder holding the substrate in the chamber;
a flash lamp emitting the flash of light to the substrate, the substrate being held by the holder;
a discharge circuit allowing a current to flow through the flash lamp and causing the flash lamp to emit the flash of light; and
a controller controlling the discharge circuit,
wherein the discharge circuit includes a first switching element connected in parallel with the flash lamp, and
the controller is configured to render the first switching element conductive to stop the emission of the flash lamp.

2. The heat treatment apparatus according to claim 1,
wherein the first switching element is a gate commutated turn-off thyristor.

3. The heat treatment apparatus according to claim 1,
wherein the discharge circuit includes a second switching element connected in series with the flash lamp, and
the controller is configured to set the second switching element in a blocking state to stop the emission of the flash lamp.

4. The heat treatment apparatus according to claim 3,
wherein the controller is configured to select which one of the first switching element and the second switching element operates, based on a recipe.

5. The heat treatment apparatus according to claim 3,
wherein the second switching element is a gate commutated turn-off thyristor or an insulated gate bipolar transistor.

6. A heat treatment apparatus that heats a substrate by emitting a flash of light to the substrate, the apparatus comprising:
a chamber housing the substrate;
a holder holding the substrate in the chamber;
a flash lamp emitting the flash of light to the substrate, the substrate being held by the holder;
a discharge circuit allowing a current to flow through the flash lamp and causing the flash lamp to emit the flash of light; and
a controller controlling the discharge circuit,
wherein the discharge circuit includes a gate commutated turn-off thyristor connected in series with the flash lamp, and
the controller is configured to set the gate commutated turn-off thyristor in a blocking state to stop the emission of the flash lamp.
